(19) United States
(12) Patent Application Publication
(10) Pub. No.: US 2025/0163563 A1
(43) Pub. Date: May 22, 2025

(54) MASK ASSEMBLY, APPARATUS AND METHOD OF MANUFACTURING DISPLAY APPARATUS

(71) Applicant: Samsung Display Co., Ltd., Yongin-si (KR)

(72) Inventors: Yuri Lee, Yongin-si (KR); Minji Jang, Yongin-si (KR); Yeonju Kang, Yongin-si (KR); Sanghoon Kim, Yongin-si (KR); Yonghwan Kim, Yongin-si (KR)

(21) Appl. No.: 18/931,594

(22) Filed: Oct. 30, 2024

(30) Foreign Application Priority Data
Nov. 21, 2023 (KR) 10-2023-0162733

(51) Int. Cl. C23C 14/04

(52) U.S. Cl. CPC C23C 14/042

(57) ABSTRACT

A mask assembly includes a mask frame including an opening area, and a mask sheet disposed to shield at least a portion of the opening area and disposed on the mask frame. The mask sheet includes a clamping portion fixed to the mask frame, a connection stick disposed to be spaced apart from the clamping portion, and a plurality of sub-masks arranged between the clamping portion and the connection stick and defining a pattern hole, and the connection stick is disposed between sub-masks adjacent to each other among the plurality of sub-masks to support each of the sub-masks, and end portions of the sub-masks disposed on the connection stick are spaced apart from each other.

This application claims priority to Korean Patent Application No. 10-2023-0162733, filed on Nov. 21, 2023, and all the benefits accruing therefrom under 35 U.S.C. § 119, the content of which in its entirety is herein incorporated by reference.

### BACKGROUND

### 1. Field

Embodiments relate to an apparatus and a method, and more particularly, to a mask assembly, an apparatus for manufacturing a display apparatus, and a method of manufacturing a display apparatus.

### 2. Description of the Related Art

Mobile electronic apparatuses are widely used. As mobile electronic apparatuses, recently, tablet personal computers (“PCs”) have been widely used as well as miniaturized electronic apparatuses such as mobile phones.

To support various functions, e.g., to provide a user with visual information such as images, the mobile electronic apparatuses include a display apparatus. Recently, as parts which drive a display apparatus are miniaturized, a proportion of the display apparatus in an electronic apparatus is gradually increased, and a structure that may be bent to form a preset angle from a flat state is also under development.

Such display apparatuses may include various layers disposed in a constant pattern on a substrate. In this case, at least one of the various layers may be formed by a mask assembly in which at least one pattern hole is defined.

### SUMMARY

A mask assembly includes a mask in which at least one pattern hole is defined, and a mask frame on which the mask is disposed. In this case, in the case where the mask is disposed on the mask frame, at least one pattern hole may not be defined in a preset position but may be defined in a different position due to the transformation of the mask. In this case, because a display apparatus manufactured through the mask assembly includes a pixel that is not disposed in a fine pattern, clear images may not be displayed. Embodiments include a mask assembly in which an opening having a fine pattern is defined, an apparatus for manufacturing a display apparatus, and a method of manufacturing the display apparatus.

Additional features will be set forth in part in the description which follows and, in part, will be apparent from the description, or may be learned by practice of the presented embodiments of the disclosure.

In an embodiment of the disclosure, a mask assembly includes a mask frame including an opening area, and a mask sheet which shields at least a portion of the opening area and is disposed on the mask frame, wherein the mask sheet includes a clamping portion fixed to the mask frame, a connection stick spaced apart from the clamping portion, and a plurality of sub-masks arranged between the clamping portion and the connection stick and defining a pattern hole, and the connection stick is disposed between sub-masks adjacent to each other among the plurality of sub-masks and supports each of the sub-masks, and end portions of the sub-masks disposed on the connection stick are spaced apart from each other.

In an embodiment, each of the sub-masks disposed on the connection stick may be coupled to the connection stick through a plurality of welding points arranged in a row.

In an embodiment, the plurality of welding points may be arranged in a direction perpendicular to a lengthwise direction of a sub-mask of the plurality of sub-masks.

In an embodiment, a width of the connection stick may be in a range of about 5 millimeters (mm) to about 100 mm.

In an embodiment, a thickness of the connection stick may be at least a thickness of a sub-mask of the plurality of sub-masks and be within a range of 1 mm or less.

In an embodiment, the sub-masks may be tensioned in a first direction and fixed to the clamping portion and the connection stick.

In an embodiment, the mask sheet may be tensioned in a second direction different from the first direction and be fixed to the mask frame.

In an embodiment, the mask assembly may further include a support stick disposed on the mask frame and crossing the opening area.

In an embodiment, the support stick may define an opening into which the connection stick is inserted.

In an embodiment of the disclosure, an apparatus for manufacturing a display apparatus includes a deposition source, and a mask assembly facing the deposition source, wherein the mask assembly includes a mask frame including an opening area, and a mask sheet which shields at least a portion of the opening area and is disposed on the mask frame, wherein the mask sheet includes a clamping portion fixed to the mask frame, a connection stick spaced apart from the clamping portion, and a plurality of sub-masks arranged between the clamping portion and the connection stick and defining a pattern hole, and the connection stick is disposed between sub-masks adjacent to each other among the plurality of sub-masks and supports each of the sub-masks, and end portions of the sub-masks disposed on the connection stick are spaced apart from each other.

In an embodiment, each of the sub-masks disposed on the connection stick may be coupled to the connection stick through a plurality of welding points arranged in a row.

In an embodiment, the plurality of welding points may be arranged in a direction perpendicular to a lengthwise direction of a sub-mask of the plurality of sub-masks.

In an embodiment, a width of the connection stick may be in a range of about 5 mm to about 100 mm.

In an embodiment, a thickness of the connection stick may be at least a thickness of a sub-mask of the plurality of sub-masks and is within a range of 1 mm or less.

In an embodiment, the sub-masks may be tensioned in a first direction and fixed to the clamping portion and the connection stick.

In an embodiment, the mask sheet may be tensioned in a second direction different from the first direction and is fixed to the mask frame.

In an embodiment, the mask assembly may further include a support stick disposed on the mask frame and crossing the opening area.

In an embodiment, the support stick may define an opening into which the connection stick is inserted.

In an embodiment of the disclosure, a method of manufacturing a display apparatus includes disposing a mask assembly and a substrate inside a chamber, and passing, through the mask assembly, a deposition material supplied from a deposition source, and depositing the deposition material on the substrate, wherein the mask assembly includes a mask frame including an opening area, and a mask sheet which shields at least a portion of the opening area and is disposed on the mask frame, wherein the mask sheet includes a clamping portion fixed to the mask frame, a connection stick spaced apart from the clamping portion, and a plurality of sub-masks arranged between the clamping portion and the connection stick and defining a pattern hole, and the connection stick is disposed between sub-masks adjacent to each other among the plurality of sub-masks and supports each of the sub-masks, and end portions of the sub-masks disposed on the connection stick are spaced apart from each other.

In an embodiment, each of the sub-masks disposed on the connection stick may be coupled to the connection stick through a plurality of welding points arranged in a row.

In an embodiment, the plurality of welding points may be disposed in a direction perpendicular to a lengthwise direction of a sub-mask of the plurality of sub-masks.

In an embodiment, a width of the connection stick may be in a range of about 5 mm to about 100 mm.

In an embodiment, a thickness of the connection stick may be at least a thickness of a sub-mask of the plurality of sub-masks and be within a range of 1 mm or less.

In an embodiment, the sub-masks may be tensioned in a first direction and fixed to the clamping portion and the connection stick.

In an embodiment, the mask sheet may be tensioned in a second direction different from the first direction and be fixed to the mask frame.

In an embodiment, a support stick may be disposed on the mask frame and crosses the opening area.

In an embodiment, the support stick may define an opening into which the connection stick is inserted.

These and/or other aspects will become apparent and more readily appreciated from the following detailed description of the embodiments, the accompanying drawings, and claims.

These general and specific aspects may be implemented by a system, a method, a computer program, or a combination of a certain system, method, and computer program.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a cross-sectional view of an embodiment of an apparatus for manufacturing a display apparatus;

FIG. 2 is a schematic perspective view of an embodiment of a mask assembly;

FIG. 3 is a schematic plan view of an embodiment of a mask sheet;

FIG. 4 is a schematic cross-sectional view of an embodiment of a mask sheet, taken along line IV-IV′ of FIG. 3;

FIG. 5 is a schematic plan view of a support stick;

FIG. 6 is a schematic cross-sectional view of an embodiment of a mask assembly, taken along line IV-IV′ of FIG. 5;

FIG. 7 is a cross-sectional view for comparing an embodiment of a mask assembly with a comparative example of a mask assembly;

FIG. 8 is a schematic plan view of an embodiment of a support stick;

FIGS. 9 and 10 are schematic plan views of embodiments of a support stick;

FIG. 11 is a schematic plan view of an embodiment of a display apparatus manufactured by an apparatus for manufacturing a display apparatus; and

FIG. 12 is a schematic cross-sectional view of an embodiment of a display apparatus manufactured by an apparatus for manufacturing a display apparatus, taken along line XII-XII′ of FIG. 11.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

An x direction, a y direction and a z direction are not limited to directions indicated by three axes of the rectangular coordinate system, and may be interpreted in a broader sense. For example, the x direction, the y direction, and the z direction may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially or performed in the opposite order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, or 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

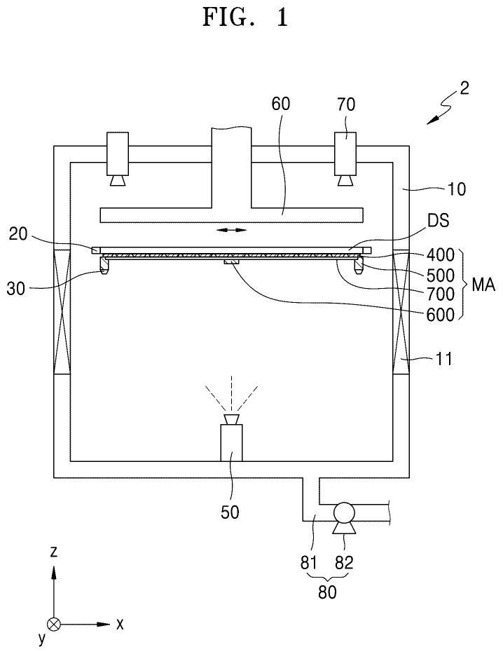

FIG. 1 is a cross-sectional view of an embodiment of an apparatus 2 for manufacturing a display apparatus.

Referring to FIG. 1, the apparatus 2 for manufacturing a display apparatus may include a chamber 10, a substrate supporter 20, a mask supporter 30, a mask assembly MA, a deposition source 50, a magnetic force portion 60, a vision portion 70, and a pressure adjustor 80.

A space may be formed inside the chamber 10. A display substrate DS and the mask assembly MA may be received in the space. In this case, a portion of the chamber 10 may be open. A gate valve 11 may be installed in the open portion of the chamber 10. In this case, the open portion of the chamber 10 may be opened or closed according to an operation of the gate valve 11.

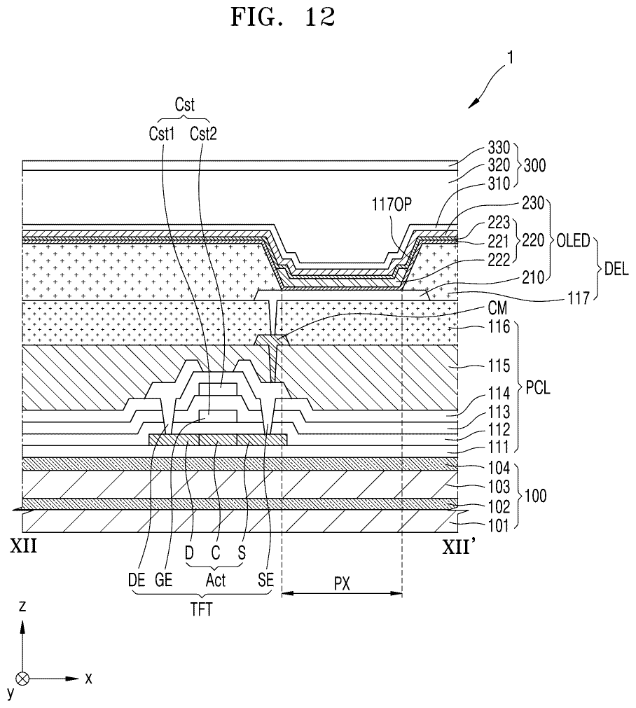

In this case, the display substrate DS may denote a structure in which at least one of an organic layer, an inorganic layer, and a metal layer is deposited on the substrate 100 (refer to FIG. 12) described below in the process of manufacturing the display apparatus. In an alternative embodiment, the display substrate DS may be the substrate 100 on which any of the organic layer, the inorganic layer, and the metal layer is not yet deposited.

The substrate supporter 20 may support the display substrate DS. In this case, the substrate supporter 20 may be a plate form fixed inside the chamber 10. In another embodiment, the substrate supporter 20 may be a shuttle form in which the display substrate DS is seated and is linearly movable inside the chamber 10. In another embodiment, the substrate supporter 20 may include an electrostatic chuck or an adhesive chuck disposed in the chamber 10 to be fixed or movable inside the chamber 10.

The mask supporter 30 may support the mask assembly MA. In this case, the mask supporter 30 may be disposed inside the chamber 10. The mask supporter 30 may fine-adjust the position of the mask assembly MA. In this case, the mask supporter 30 may include a separate driver, an alignment unit, or the like to move the mask assembly MA in different directions.

In another embodiment, the mask supporter 30 may be a shuttle form. In this case, the mask assembly MA may be seated on the mask supporter 30. The mask supporter 30 may transfer the mask assembly MA. In an embodiment, the mask supporter 30 may move to the outside of the chamber 10, and after the mask assembly MA is seated on the mask supporter 30, the mask supporter 30 may enter the inside of the chamber 10 from the outside of the chamber 10.

In this case, the substrate supporter 20 may be unitary with the mask supporter 30. In this case, the substrate supporter 20 and the mask supporter 30 may include a movable shuttle. In this case, the substrate supporter 20 and the mask supporter 30 may include a structure which fixes the mask assembly MA to the display substrate DS with the display substrate DS seated on the mask assembly MA, and linearly move the display substrate DS and the mask assembly MA simultaneously.

Hereinafter, for convenience of description, a form in which the substrate supporter 20 and the mask supporter 30 are discriminated from each other and disposed at different positions, and a form in which the substrate supporter 20 and the mask supporter 30 are disposed inside the chamber 10, are mainly described in detail.

The deposition source 50 may be disposed to face the mask assembly MA. In this case, a deposition material may be received in the deposition source 50. The deposition material may be evaporated or sublimated by applying heat to the deposition material. The deposition source 50 may be fixed inside the chamber 10, or disposed inside the chamber 10 to be linearly movable in one direction.

The mask assembly MA may be disposed inside the chamber 10. In this case, the mask assembly MA may include a mask frame 500 and a mask sheet 400. This is described below in detail. The deposition material may pass through the mask assembly MA and be deposited on the display substrate DS.

The magnetic force portion 60 may be disposed inside the chamber 10 to face the display substrate DS and/or the mask assembly MA. In this case, the magnetic force portion 60 may apply magnetic force to the mask assembly MA and attract the mask assembly MA toward the display substrate DS. Particularly, the magnetic force portion 60 may not only prevent sagging of the mask sheet 400 but also allow the mask sheet 400 to be adjacent to the display substrate DS. In addition, the magnetic force portion 60 may maintain a uniform interval between the mask sheet 400 and the display substrate DS.

The vision portion 70 may be disposed in the chamber 10 and may capture the positions of the display substrate DS and the mask assembly MA. In this case, the vision portion 70 may include a camera which captures the display substrate DS and the mask assembly MA. The positions of the display substrate DS and the mask assembly MA may be determined based on the images captured by the vision portion 70, and the transformation of the mask assembly MA may be determined. In addition, the substrate supporter 20 may fine-adjust the position of the display substrate DS or the mask supporter 30 may fine-adjust the position of the mask assembly MA based on the captured images. Hereinafter, the case where the mask supporter 30 fine-adjusts the position of the mask assembly MA and align the positions of the display substrate DS and the mask assembly MA, is mainly described in detail.

The pressure adjustor 80 may be connected to the chamber 10 and adjust the inner pressure of the chamber 10. In an embodiment, the pressure adjustor 80 may adjust the inner pressure of the chamber 10 to be equal or similar to the atmospheric pressure. In addition, the pressure adjustor 80 may adjust the inner pressure of the chamber 10 to be equal or similar to a vacuum state.

The pressure adjustor 80 may include a connection pipe 81 and a pump 82, wherein the connection pipe 81 is connected to the chamber 10, and the pump 82 is installed to the connection pipe 81. In this case, external air may be introduced through the connection pipe 81 or a gas inside the chamber 10 may be guided to the outside through the connection pipe 81 according to an operation of the pump 82.

A method of manufacturing a display apparatus (not shown) by the apparatus 2 for manufacturing a display apparatus, is described. First, the display substrate DS may be prepared.

The pressure adjustor 80 may maintain the inside of the chamber 10 at a state equal or similar to the atmospheric pressure. The gate valve 11 may operate to open the open portion of the chamber 10.

Then, the display substrate DS may be loaded into the inside of the chamber 10 from the outside. In this case, the display substrate DS may be loaded into the chamber 10 in various methods. In an embodiment, the display substrate DS may be loaded into the inside of the chamber 10 from the outside of the chamber 10 by a robot arm disposed outside the chamber 10. In another embodiment, in the case where the substrate supporter 20 is formed in a shuttle form, the substrate supporter 20 may be carried from the inside of the chamber 10 to the outside of the chamber 10, then, the display substrate DS may be seated on the substrate supporter 20 by a separate robot arm disposed outside the chamber 10, and the substrate supporter 20 may be loaded into the inside of the chamber 10 from the outside of the chamber 10.

The mask assembly MA may be disposed inside the chamber 10 as described above. In another embodiment, in the equal or similar manner to the display substrate DS, the mask assembly MA may be loaded into the inside of the chamber 10 from the outside of the chamber 10.

When the display substrate DS is loaded into the inside of the chamber 10, the display substrate DS may be seated on the substrate supporter 20. In this case, the vision portion 70 may capture the positions of the display substrate DS and the mask assembly MA. The positions of the display substrate DS and the mask assembly MA may be determined based on images captured by the vision portion 70. In this case, the apparatus 2 for manufacturing a display apparatus may include a separate controller (not shown) to determine the positions of the display substrate DS and the mask assembly MA.

When the determination of the positions of the display substrate DS and the mask assembly MA is completed, the mask supporter 30 may fine-adjust the position of the mask assembly MA.

Then, the deposition source 50 operates to supply the deposition material toward the mask assembly MA, and the deposition material passing through a plurality of pattern holes of the mask sheet 400 may be deposited on the display substrate DS. In this case, the deposition source 50 may move in parallel to the display substrate DS and the mask assembly MA, or the display substrate DS and the mask assembly MA may move in parallel to the deposition source 50. That is, the deposition source 50 may move relative to the display substrate DS and the mask assembly MA. In this case, the pump 82 may maintain the pressure of the chamber 10 at a state equal or similar to vacuum by sucking in the gas inside the chamber 10 and discharging the gas to the outside.

As described above, the deposition material supplied from the deposition source 50 may pass through the mask assembly MA, be deposited on the display substrate DS, and thus, form at least one of a plurality of layers, e.g., an organic layer, an inorganic layer, and a metal layer stacked in the display apparatus described below.

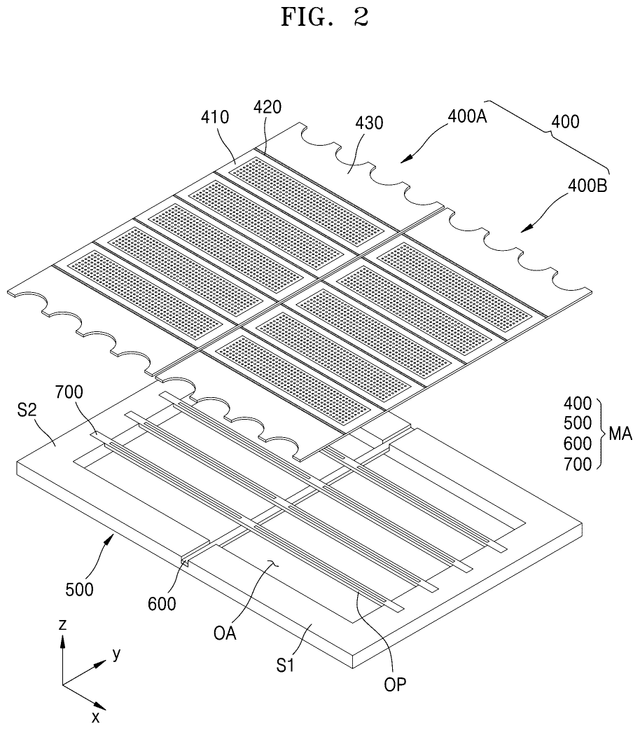

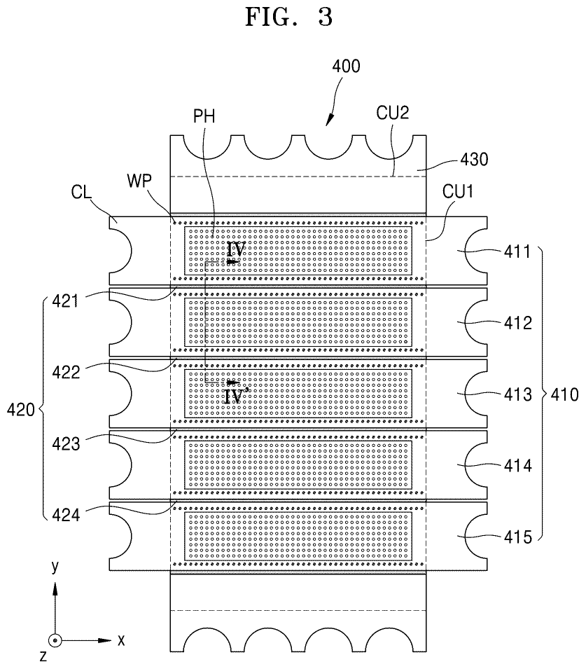

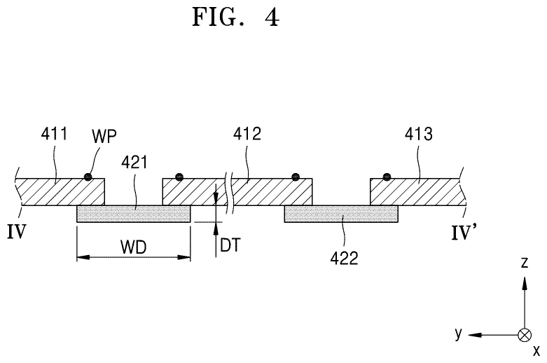

FIG. 2 is a schematic perspective view of an embodiment of the mask assembly MA and shows the mask assembly MA that may be used in the apparatus 2 (refer to FIG. 1) for manufacturing a display apparatus. FIG. 3 is a schematic plan view of an embodiment of the mask sheet 400. FIG. 4 is a schematic cross-sectional view of an embodiment of the mask sheet 400, taken along line IV-IV′ of FIG. 3.

Referring to FIGS. 2 to 4, the mask assembly MA may include the mask frame 500, the mask sheet 400, a shielding stick 600, and a support stick 700.

The mask frame 500 may include a plurality of sides connected to each other and include an opening area OA defined by the plurality of sides. That is, the opening area OA may be surrounded by the plurality of sides and may pass through the center of the mask frame 500.

In an embodiment, the mask frame 500 may be a quadrangular frame. However, the shape of the mask frame 500 is not limited thereto but may be various other polygonal shapes. Hereinafter, for convenience of description, the case where the mask frame 500 is a quadrangular frame is mainly described.

In the case where the mask frame 500 is a quadrangular frame, the plurality of sides may include a first side S1 extending in a first direction (e.g., an x direction in FIG. 2) and a second side S2 extending in a second direction (e.g., a y direction in FIG. 2) crossing the first direction. Because the first side S1 is provided as a pair to face each other, and the second side S2 is provided as a pair to face each other, the first side S1 may be connected to the second side S2. In an embodiment, the first side S1 may be a long side, and the second side S2 may be a short side. However, the disclosure is not limited thereto but the first side S1 may be a short side and the second side S2 may be a long side, or the length of the first side S1 may be equal to the length of the second side S2. Hereinafter, for convenience of description, the case where the first side S1 is a long side and the second side S2 is a short side is mainly described.

The mask sheet 400 may be tensioned in a lengthwise direction (e.g., a second direction) of the mask sheet 400 and fixed to the mask frame 500. The opening area OA in the center of the mask frame 500 may be covered by the mask sheet 400. Although it is shown in FIG. 2 that the mask sheet 400 includes a first mask sheet 400A and a second mask sheet 400B, at least one mask sheet 400 may be provided in an embodiment. In the case where two or more mask sheets 400 are provided, the mask sheets 400 may be disposed on the mask frame 500 to be parallel to each other. In an embodiment, the mask sheets 400 may be arranged in parallel to each other in the first direction (e.g., the x direction in FIG. 2). Two opposite end portions of the mask sheet 400 may be fixed to the mask frame 500 by welding, for example.

In an embodiment, the mask sheet 400 may be an extended mask sheet 400 in which a plurality of sub-masks 410 is connected to each other. Because the mask sheet 400 may form the mask sheet 400 having a substantially wide width (a length in the x direction of FIG. 3), a display apparatus having a substantially wide width may be manufactured.

In an embodiment, the mask sheet 400 may include the sub-mask 410, a connection stick 420, and a main clamping portion 430. Although the sub-mask 410 may be a mask extending in the first direction (the x direction of FIG. 3) in an embodiment, the disclosure is not limited thereto. The sub-mask 410 may be provided in plurality. In an embodiment, the sub-mask 410 may include a first sub-mask 411, a second sub-mask 412, a third sub-mask 413, a fourth sub-mask 414, and a fifth sub-mask 415. Although the sub-mask 410 may include five sub-masks as shown in FIG. 3, the disclosure is not limited thereto and the sub-mask 410 may include less than five sub-masks or more than five sub-masks. Hereinafter, for convenience of description, the first sub-mask 411, the second sub-mask 412, and the third sub-mask 413 are mainly described.

Each sub-mask 410 may define at least one pattern hole PH. The pattern hole PH may be a through hole defined to enable a deposition material to pass through the sub-mask 410. The deposition material passing through the sub-mask 410 may be deposited on the display substrate DS (refer to FIG. 1).

The first sub-mask 411, the second sub-mask 412, and the third sub-mask 413 may be arranged in the second direction (the y direction of FIG. 3) crossing the first direction. The first sub-mask 411, the second sub-mask 412, and the third sub-mask 413 may be apart by a preset interval from each other in the second direction.

The plurality of sub-masks 410, e.g., the first sub-mask 411, the second sub-mask 412, and the third sub-mask 413 may be connected to each other by the connection stick 420. Specifically, the first sub-mask 411 and the second sub-mask 412 apart from each other in the second direction may be connected to each other by a first supporter 421. As shown in FIG. 4, the first supporter 421 may be disposed to overlap a portion of the first sub-mask 411 and the second sub-mask 412. In this case, the first supporter 421 may be disposed on the lower surface (e.g., a surface in a −z direction of FIG. 4) of the first sub-mask 411 and the lower surface of the second sub-mask 412. In an embodiment, the first supporter 421 may be fixed to the first sub-mask 411 and the second sub-mask 412 by performing spot-welding on welding points WP disposed at the upper surfaces of the first sub-mask 411 and the second sub-mask 412.

Similarly, the second sub-mask 412 and the third sub-mask 413 apart from each other in the second direction may be connected to each other by a second supporter 422. As shown in FIG. 4, the second supporter 422 may be disposed to overlap a portion of the second sub-mask 412 and the third sub-mask 413. In this case, the second supporter 422 may be disposed on the lower surface of the second sub-mask 412 and the lower surface of the third sub-mask 413. In an embodiment, the second supporter 422 may be fixed to the second sub-mask 412 and the third sub-mask 413 by performing spot-welding on welding points WP disposed at the upper surfaces of the second sub-mask 412 and the third sub-mask 413. In this case, a plurality of welding points WP may be disposed in a row on the upper surface of each of the first sub-mask 411 and the second sub-mask 412, and the third sub-mask 413. In this case, the plurality of welding points WP may be arranged in a lengthwise direction (e.g., the y direction of FIG. 2) of each of the first sub-mask 411 and the second sub-mask 412, and the third sub-mask 413.

The connection stick 420 may extend in the extension direction of the sub-mask 410, e.g., in the first direction. The connection stick 420 may connect sub-masks 410 adjacent to each other while shielding a portion between the sub-masks 410 adjacent to each other.

In addition, in an embodiment, the connection stick 420 may be disposed under the sub-mask 410. That is, because the connection stick 420 is welded and connected to the lower surface of the sub-mask 410, a step difference may be formed.

A width WD of the connection stick 420 may be in a range of about 5 mm to about 100 mm. In this case, in the case where the width WD of the connection stick 420 is less than 5 mm, the connection stick 420 may not support the sub-mask 410 and also may not fix another sub-mask 410 to the connection stick 420 due to transformation of the connection stick 420 while the sub-mask 410 is welded to the connection stick 420. In addition, in the case where the width WD of the connection stick 420 exceeds 100 mm, the weight of the connection stick 420 itself increases and transformation of the mask sheet 400 due to the weight of the connection stick 420 may be caused, or a portion on which the connection stick 420 is disposed may sag. In this case, the width WD of the connection stick 420 may be measured in the second direction (the y direction of FIG. 3).

A thickness DT of the connection stick 420 may be in a range of about the thickness of the sub-mask 410 to about 1 mm. In this case, when the thickness DT of the connection stick 420 is less than the thickness of the sub-mask 410, the connection stick 420 may not support the sub-mask 410 disposed on the connection stick 420 and also the transformation of the connection stick 420 may become excessive due to heat generated during the welding in the case where the sub-mask 410 is fixed to the connection stick 420. In addition, in the case where the thickness DT of the connection stick 420 exceeds 1 mm, the mask sheet 400 itself may sag due to the weight of the connection stick 420.

The thickness DT of the connection stick 420 may be measured in a third direction (e.g., a z direction). The thickness DT of the connection stick 420 may be 1 mm or less. Preferably, the thickness of the sub-mask 410 may be about 15 micrometers (μm) to about 18 μm.

Clamping portions CL disposed on two opposite ends in the transverse direction (e.g., the x direction of FIG. 3) of each sub-mask 410 may be used to clamp and tension each sub-mask 410 when connecting the sub-masks 410 to each other. In this case, each sub-mask 410 may be tensioned in the first direction (e.g., the x direction of FIG. 3). The clamping portions CL of each sub-mask 410 may connect the sub-masks 410 and then be cut off as shown in FIG. 2. In an embodiment, a portion of the clamping portion CL may be cut off along a first cutting line CU1 to form the outline of the mask sheet 400.

The main clamping portions 430 may be connected to the sub-masks 410 disposed on two opposite ends in the second direction among the plurality of sub-masks 410 disposed side-by-side in the second direction. In an embodiment, as in FIG. 3, the main clamping portions 430 may be respectively connected to the first sub-mask 411 and the fifth sub-mask 415. As similarly described above, the main clamping portions 430 may be connected to the sub-masks 410 by the connection stick 420. The main clamping portions 430 may be used to clamp and tension the mask sheet 400 in the second direction when welding and fixing the mask sheet 400 to the mask frame 500. In an embodiment, the main clamping portions 430 may be cut off after the mask sheet 400 is fixed to the mask frame 500. In an embodiment, a portion of the main clamping portions 430 may be cut off along a second cutting line CU2. In this case, the end of the mask sheet 400 disposed on the mask frame 500 may be form a straight line to be substantially coincide with the edge of the mask frame 500.

Referring back to FIG. 2, the shielding stick 600 may be disposed between the mask frame 500 and the mask sheet 400 to shield spaces between the plurality of mask sheets 400. In an embodiment, the shielding stick 600 may be provided as one element to shield the first mask sheet 400A and the second mask sheet 400B. In another embodiment, in the case where three or more mask sheets 400 are provided, the shielding stick 600 may be provided in plurality and the plurality of shielding sticks 600 may be spaced apart from each other in the first direction to be parallel to each other. In addition, the shielding stick 600 may extend in the second direction (e.g., the y direction of FIG. 2) to cross the inside of the mask frame 500, that is, the opening area OA. Grooves for receiving two opposite ends of the shielding stick 600 may be defined in the mask frame 500. The shielding stick 600 may be disposed between the plurality of mask sheets 400 to shield the space between two adjacent mask sheets 400 such that the deposition materials do not pass through the space between two adjacent mask sheets 400.

The support stick 700 may extend in the first direction (e.g., the x direction of FIG. 2) to cross the inside of the mask frame 500, that is, the opening area OA. In an embodiment, the support stick 700 may be provided in plurality, and the plurality of support sticks 700 may be spaced apart from each other in the second direction (e.g., the y direction of FIG. 2) to be parallel to each other. The support stick 700 may cross the shielding stick 600 and be disposed on the shielding stick 600 in the opening area OA. In addition, grooves for receiving two opposite end portions of the support stick 700 may be defined in the mask frame 500, but the disclosure is not limited thereto. The support stick 700 may prevent the sagging of the mask sheet 400 by supporting the mask sheet 400 in the opening area OA.

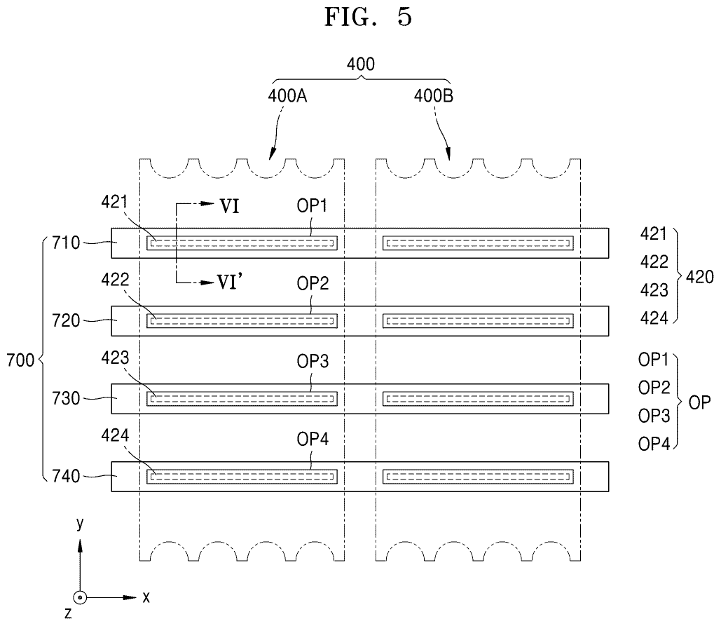

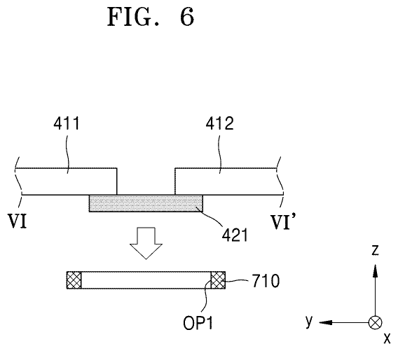

FIG. 5 is a schematic plan view of the support stick 700. FIG. 6 is a schematic cross-sectional view of an embodiment of the mask assembly, taken along line IV-IV′ of FIG. 5.

Referring to FIGS. 5 and 6, in an embodiment, the support stick 700 may be disposed to overlap the connection stick 420 of the mask sheet 400 in a plan view. Specifically, the support stick 700 may include a first support stick 710, a second support stick 720, a third support stick 730, and a fourth support stick 740. The first support stick 710 may extend to cross the mask sheet 400. In an embodiment, the first support stick 710 may extend in the first direction between the first sub-mask 411 and the second sub-mask 412. In this case, the first support stick 710 may be disposed to overlap the first supporter 421 of the mask sheet 400. Similarly to this, it may be understood that the second support stick 720 to the fourth support stick 740 may be disposed to overlap the second supporter 422, a third supporter 423 and a fourth supporter 424 of the mask sheet 400, respectively. Because each of the second support stick 720 to the fourth support stick 740 is similar to the first support stick 710, hereinafter, the first support stick 710 is mainly described.

In an embodiment, each of the support sticks 700 may define an opening OP. In an embodiment, the opening OP may include a first opening OP1, a second opening OP2, a third opening OP3, and a fourth opening OP4 respectively defined in the first support stick 710, the second support stick 720, the third support stick 730 and the fourth support stick 740. The opening OP may be a through hole extending in an extension direction of the support stick 700, e.g., in the first direction. In an embodiment, the opening OP may be defined by the number of mask sheets 400. In an embodiment, as shown in FIG. 2, in the case where two mask sheets 400 are provided, each of the support sticks 700 may define two openings OP to correspond to the first mask sheet 400A and the second mask sheet 400B.

The opening OP may receive the connection stick 420. That is, because the width of the opening OP is defined greater than the width (e.g., a length in the y direction of FIG. 5) of the connection stick 420, the connection stick 420 may be received in the opening OP. Accordingly, as shown in FIG. 5, the connection stick 420 may be received in the opening OP defined in the support stick 700, and the sub-mask 410 (refer to FIG. 2) may be supported by being in contact with the support stick 700. In this case, because the connection stick 420 is not disposed on the support stick 700 but is received inside the support stick 700, a step difference between the support stick 700 and the sub-mask 410 may be prevented.

In addition, in an embodiment, the width of the opening OP may be defined greater by about 12 μm to about 18 μm than the width of the connection stick 420. Accordingly, while securing a tolerance for receiving the connection stick 420, it is possible to ensure that cleaning liquid is easily discharged without pooling between the support stick 700 and the connection stick 420 when cleaning the mask assembly MA (refer to FIG. 2).

In addition, in an embodiment, the thickness (a length in the z direction) of the connection stick 420 may be equal to the thickness (a length in the z direction) of the support stick 700. Accordingly, in the case where the mask sheet 400 is supported by the support sticks 700, the sub-masks 410 may be supported by being in contact with the support sticks 700, and a step difference may not be formed between the connection stick 420 and the support stick 700.

Although it is shown in FIG. 5 that the width of the connection stick 420 measured in the first direction is less than the width of the mask sheet 400, the disclosure is not limited thereto. In an embodiment, as shown in FIG. 3, the width of the connection stick 420 measured in the first direction may be equal to the width of the mask sheet 400. In another embodiment, although not shown in the drawing, the width of the connection stick 420 measured in the first direction may be greater than the width of the mask sheet 400.

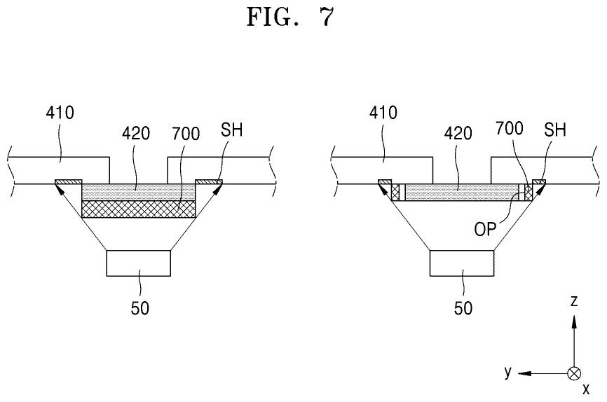

FIG. 7 is a cross-sectional view for comparing an embodiment of the mask assembly with a comparative example of a mask assembly. Specifically, the mask assembly in an embodiment is shown on the right, and the mask assembly according to the comparative example is shown on the left.

Referring to FIG. 7, the mask assembly in an embodiment may prevent a shadow phenomenon. A shadow phenomenon denotes that when deposition materials pass through the mask sheet 400 and are deposited on the display substrate DS, the deposition materials are not deposited to a normal deposition thickness. In the case where the connection stick 420 is disposed on the support stick 700 as in the comparative example, a distance between the deposition source 50 and the support stick 700 may be reduced compared to an embodiment. Accordingly, a non-deposition region SH in which the deposition materials are screened by the support stick 700 and are not deposited may increase. In contrast, in an embodiment, because the connection stick 420 is received in the opening OP of the support stick 700, a distance between the deposition source 50 and the support stick 700 may increase compared to the comparative example. Accordingly, the non-deposition region SH in which the deposition materials are screened by the support stick 700 and are not deposited may be reduced and a shadow phenomenon may be prevented.

In addition, according to the comparative example, pooling of the cleaning liquid used to clean the mask assembly MA (refer to FIG. 2) may occur where the connection stick 420 and the support stick 700 contact each other. Due to this, the cleaning liquid may not drain easily, reducing the life of the mask assembly MA. In contrast, in an embodiment, the connection stick 420 is received in the opening OP of the support stick 700, and the cleaning liquid may drain easily through the opening OP, and thus, pooling of the cleaning liquid between the connection stick 420 and the support stick 700 may be prevented.

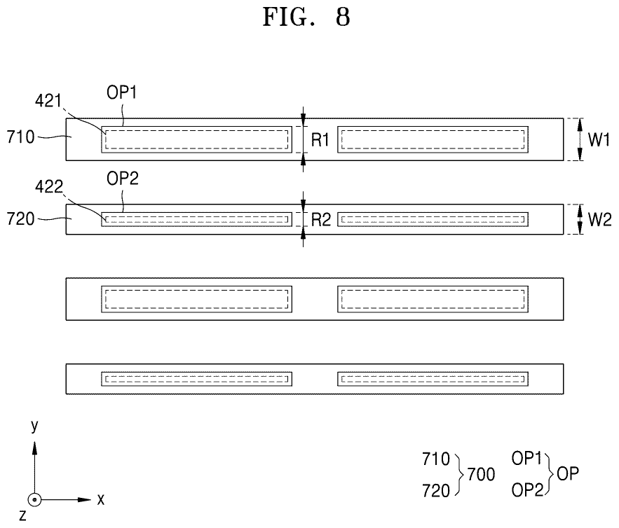

FIG. 8 is a schematic plan view of an embodiment of the support stick 700. Because the support stick 700 in the illustrated embodiment is similar to the support stick 700 described above, differences are mainly described below.

Referring to FIG. 8, in an embodiment, a width W1 of the first support stick 710 may be different from a width W2 of the second support stick 720. In an embodiment, the width W1 of the first support stick 710 may be greater than the width W2 of the second support stick 720. In addition, in an embodiment, a width R1 of the opening OP, that is, the first opening OP1 of the first support stick 710 may be different from a width R2 of the opening OP, that is, the second opening OP2 of the second support stick 720. In an embodiment, the width R1 of the first opening OP1 may be greater than the width R2 of the second opening OP2.

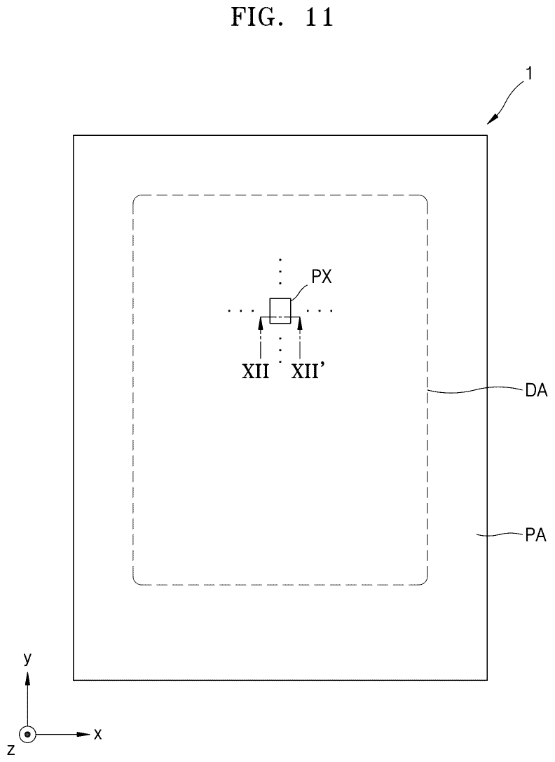

Because the width W1 of the first support stick 710 is different from a width W2 of the second support stick 720, and the width R1 of the first opening OP1 is different from the width R2 of the second opening OP2, the display apparatuses 1 (refer to FIG. 11) of various sizes may be manufactured. In an embodiment, the sizes of the first sub-mask 411 (refer to FIG. 3) and the second sub-mask 412 (refer to FIG. 3) may be different from each other, and the sizes of the second sub-mask 412 and the third sub-mask 413 (refer to FIG. 3) may be different from each other. Accordingly, the width of the first supporter 421 connecting the first sub-mask 411 to the second sub-mask 412 may need to be different from the width of the second supporter 422 connecting the second sub-mask 412 to the third sub-mask 413. Accordingly, the widths of the first opening OP1 and the second opening OP2 respectively receiving the first supporter 421 and the second supporter 422 may need to be different from each other. In addition, the width W1 of the first support stick 710 may need to be different from the width W2 of the second support stick 720.

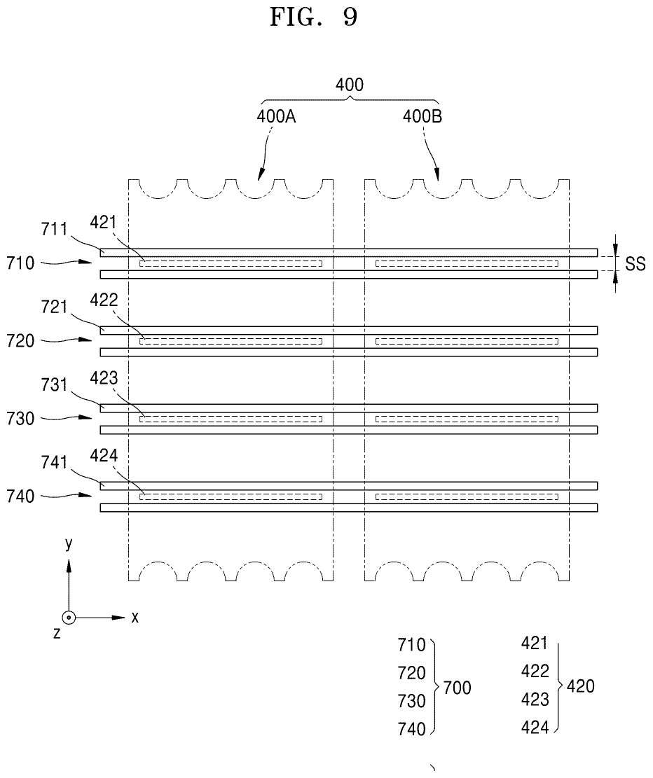

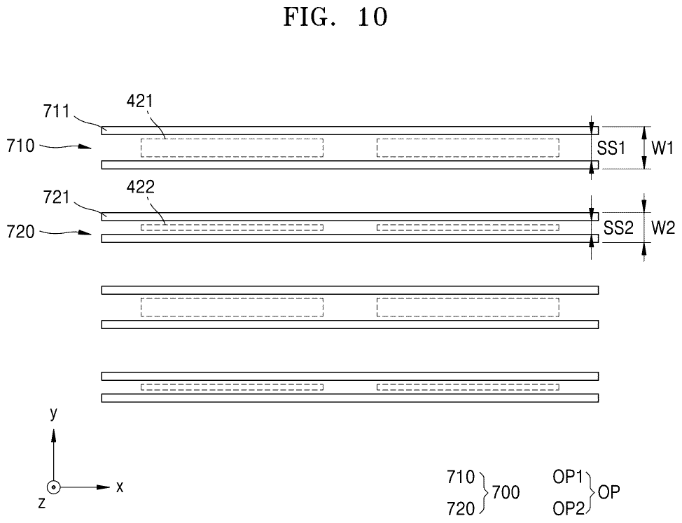

FIGS. 9 and 10 are schematic plan views of embodiments of the support stick 700. Because the support stick 700 in the illustrated embodiment is similar to the support stick 700 described above, differences are mainly described below.

Referring to FIG. 9, in an embodiment, the support stick 700 may include a pair of parallel sub-sticks extending in the first direction. In an embodiment, the first support stick 710 may include a pair of parallel first sub-sticks 711 extending in the first direction. In this case, a pair of parallel first sub-sticks 711 may be spaced apart from each other in the second direction. A distance between a pair of parallel first sub-sticks 711 may be defined as a separation distance SS. In an embodiment, the second support stick 720 may include a pair of parallel second sub-sticks 721 extending in the first direction, the third support stick 730 may include a pair of parallel third sub-sticks 731 extending in the first direction, and the fourth support stick 740 may include a pair of parallel fourth sub-sticks 741 extending in the first direction.

The connection stick 420 may be received between a pair of parallel first sub-sticks 711. In this case, the separation distance SS may be greater than the width of the connection stick 420 by about 12 μm to about 18 μm. Accordingly, the support stick 700 may secure a tolerance for receiving the connection stick 420, and simultaneously, ensure that the cleaning liquid is not pooled between the support stick 700 and the connection stick 420 and is easily drained when cleaning the mask assembly MA (refer to FIG. 2).

Although it is shown in FIG. 9 that the width of the connection stick 420 measured in the first direction is less than the width of the mask sheet 400, the disclosure is not limited thereto. In an embodiment, as shown in FIG. 3, the width of the connection stick 420 measured in the first direction may be equal to the width of the mask sheet 400. In another embodiment, although not shown in the drawing, the width of the connection stick 420 measured in the first direction may be greater than the width of the mask sheet 400.

Referring to FIG. 10, in an embodiment, the first support stick 710 may include a pair of parallel first sub-sticks 711 extending in the first direction. In this case, a pair of parallel first sub-sticks 711 may be spaced apart from each other by a separation distance SS1. In addition, the second support stick 720 may include a pair of parallel second sub-sticks 721 extending in the first direction. In this case, a pair of parallel second sub-sticks 721 may be spaced apart from each other by the separation distance SS2.

In this case, in an embodiment, the width W1 of the first support stick 710 may be different from the width W2 of the second support stick 720. In an embodiment, the width W1 of the first support stick 710 may be greater than the width W2 of the second support stick 720. In addition, in an embodiment, the separation distance SS1 between the first sub-sticks 711 may be different from the separation distance SS2 between the second sub-sticks 721. In an embodiment, the separation distance SS1 between the first sub-sticks 711 may be greater than the separation distance SS2 between the second sub-sticks 721.

Because the width W1 of the first support stick 710 is different from the width W2 of the second support stick 720, and the separation distance SS1 between the first sub-sticks 711 is different from the separation distance SS2 between the second sub-sticks 721, the display apparatus 1 (refer to FIG. 11) of various sizes may be manufactured. In an embodiment, the sizes of the first sub-mask 411 (refer to FIG. 3) and the second sub-mask 412 (refer to FIG. 3) may be different from each other, and the sizes of the second sub-mask 412 and the third sub-mask 413 (refer to FIG. 3) may be different from each other. Accordingly, the width of the first supporter 421 connecting the first sub-mask 411 to the second sub-mask 412 may need to be different from the width of the second supporter 422 connecting the second sub-mask 412 to the third sub-mask 413. Accordingly, the separation distance SS1 between the first sub-sticks 711 and the separation distance SS2 between the second sub-sticks 721 respectively receiving the first supporter 421 and the second supporter 422 may need to be different from each other. In addition, the width W1 of the first support stick 710 may need to be different from the width W2 of the second support stick 720.

FIG. 11 is a schematic plan view of an embodiment of a display apparatus manufactured by an apparatus 2 for manufacturing the display apparatus 1.

Referring to FIG. 11, the display apparatus 1 manufactured in an embodiment may include a display area DA and a peripheral area PA outside the display area DA. The display apparatus 1 may display images through an array of a plurality of pixels PX disposed two-dimensionally in the display area DA.

The peripheral area PA is an area that does not display images and may surround the display area DA entirely or partially. A driver or the like configured to provide electric signals or power to pixel circuits respectively corresponding to the pixels PX may be disposed in the peripheral area PA. A pad may be disposed in the peripheral area PA, wherein the pad is a region to which electronic elements or a printed circuit board may be electrically connected.

Hereinafter, though the display apparatus 1 includes an organic light-emitting diode OLED (refer to FIG. 12) as a light-emitting diode, the display apparatus 1 according to the disclosure is not limited thereto. In another embodiment, the display apparatus 1 may be a light-emitting display apparatus including an inorganic light-emitting diode, that is, an inorganic light-emitting display apparatus. The inorganic light-emitting diode may include a PN-junction diode including inorganic semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width in the range of several micrometers to hundreds of micrometers. In an embodiment, the inorganic light-emitting diode may be denoted by a micro light-emitting diode. In another embodiment, the display apparatus 1 may be a quantum-dot light-emitting display apparatus.

The display apparatus 1 may be used as a display screen in various products including televisions, notebook computers, monitors, advertisement boards, Internet of things (“IoT”) apparatuses as well as portable electronic apparatuses including mobile phones, smartphones, tablet personal computers (“PC”), mobile communication terminals, electronic organizers, electronic books, portable multimedia players (“PMP”), navigation apparatuses, and ultra mobile personal computers (“UMPC”). In addition, the display apparatus 1 in an embodiment may be used in wearable devices including smartwatches, watchphones, glasses-type displays, and head-mounted displays (“HMD”). In addition, in an embodiment, the display apparatus 1 may be used as a display screen in instrument panels for automobiles, center fascias for automobiles, or center information displays (“CIDs”) disposed on a dashboard for automobiles, room mirror displays that replace side mirrors of automobiles, and displays of an entertainment system disposed on the backside of front seats for backseat passengers in automobiles.

FIG. 12 is a schematic cross-sectional view of an embodiment of the display apparatus 1 manufactured by an apparatus 2 for manufacturing a display apparatus, taken along line XII-XII′ of FIG. 11.

Referring to FIG. 12, the display apparatus 1 may include a stack structure of the substrate 100, a pixel circuit layer PCL, a display element layer DEL, and an encapsulation layer 300. The display substrate DS (refer to FIG. 1) may be a structure in which at least one of, e.g., the pixel circuit layer PCL, the display element layer DEL, and the encapsulation layer 300 is stacked on the substrate 100 during a process of manufacturing the display apparatus 1.

The substrate 100 may have a multi-layered structure including a base layer that includes the polymer resin and an inorganic layer. In an embodiment, the substrate 100 may include the base layer including a polymer resin and a barrier layer including an inorganic insulating layer. In an embodiment, the substrate 100 may include a first base layer 101, a first barrier layer 102, a second base layer 103, and a second barrier layer 104 that are sequentially stacked. The first base layer 101 and the second base layer 103 may each include polyimide (“PI”), polyethersulfone (“PES”), polyacrylate, polyetherimide (“PEI”), polyethylene naphthalate (“PEN”), polyethylene terephthalate (“PET”), polyphenylene sulfide (“PPS”), polycarbonate (“PC”), cellulose tri acetate (“TAC”), and/or cellulose acetate propionate (“CAP”). The first barrier layer 102 and the second barrier layer 104 may each include an inorganic insulating material such as silicon oxide, silicon oxynitride, and/or silicon nitride. The substrate 100 may be flexible.

The pixel circuit layer PCL is disposed on the substrate 100. It is shown in FIG. 12 that the pixel circuit layer PCL includes a thin-film transistor TFT, a buffer layer 111, a first gate insulating layer 112, a second gate insulating layer 113, an inter-insulating layer 114, and a first planarization insulating layer 115, and a second planarization insulating layer 116 under and/or on elements of the thin-film transistor TFT.

A buffer layer 111 may reduce or block foreign materials, moisture, or external air penetrating from below the substrate 100 and may provide a flat surface on the substrate 100. The buffer layer 111 may include an inorganic insulating material such as silicon nitride, silicon oxynitride, and/or silicon oxide, and include a single-layered structure or a multi-layered structure including the above materials.

The thin-film transistor TFT on the buffer layer 111 may include a semiconductor layer Act, and the semiconductor layer Act may include polycrystalline silicon. In an alternative embodiment, the semiconductor layer Act may include amorphous silicon, an oxide semiconductor, or an organic semiconductor. The semiconductor layer Act may include a channel region C, and a drain region D, and a source region S respectively disposed on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and/or titanium (Ti) and have a single-layered structure or a multi-layered structure including the above materials.

The first gate insulating layer 112 between the semiconductor layer Act and the gate electrode GE may include an inorganic insulating material including silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

An upper electrode Cst2 of the storage capacitor Cst may be disposed on the second gate insulating layer 113. The upper electrode Cst2 may overlap the gate electrode GE therebelow. In this case, the gate electrode GE and the upper electrode Cst2 overlapping each other with the second gate insulating layer 113 therebetween, may constitute the storage capacitor Cst. That is, the gate electrode GE may serve as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single-layered structure or a multi-layered structure including the above materials.

The inter-insulating layer 114 may cover the upper electrode Cst2. The inter-insulating layer 114 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂). The inter-insulating layer 114 may include a single-layered structure or a multi-layered structure including the inorganic insulating material.

A drain electrode DE and a source electrode SE may each be disposed on the inter-insulating layer 114. The drain electrode DE and the source electrode SE may be respectively connected to the drain region D and the source region S through contact holes of insulating layers therebelow. The drain electrode DE and the source electrode SE may each include a material having relatively high conductivity. The drain electrode DE and the source electrode SE may each include a conductive material including molybdenum (Mo), aluminum (Al), copper (Cu), and/or titanium (Ti) and include a single-layered structure or a multi-layered structure including the above materials. In an embodiment, the drain electrode DE and the source electrode SE may each have a multi-layered structure of Ti/Al/Ti.

The first planarization insulating layer 115 may cover the drain electrode DE and the source electrode SE. The first planarization insulating layer 115 may include an organic insulating material including a general-purpose polymer such as polystyrene (“PS”), polymethylmethacrylate (“PMMA”), polymer derivatives having a phenol-based group, an acrylic-based polymer, an imide-based polymer, an aryl ether-based polymer, an amide-based polymer, a fluorine-containing polymer, a p-xylene-based polymer, a vinyl alcohol-based polymer, and/or any combinations thereof.

The second planarization insulating layer 116 may be disposed on the first planarization insulating layer 115. The second planarization insulating layer 116 may include the same material as a material of the first planarization insulating layer 115 and may include an organic insulating material including a general-purpose polymer such as PS, PMMA, polymer derivatives having a phenol-based group, an acrylic-based polymer, an imide-based polymer, an aryl ether-based polymer, an amide-based polymer, a fluorine-containing polymer, a p-xylene-based polymer, a vinyl alcohol-based polymer, and/or any combinations thereof.

The display element layer DEL may be disposed on the pixel circuit layer PCL having the above structure. The display element layer DEL may include an organic light-emitting diode OLED as a display element (that is, a light-emitting element). The organic light-emitting diode OLED may have a stack structure of a pixel electrode 210, an intermediate layer 220, and a common electrode 230. The organic light-emitting diode OLED may emit red, green, or blue light, or emit red, green, blue, or white light, for example. The organic light-emitting diode OLED may emit light through an emission area. The emission area may be defined as a pixel PX.

The pixel electrode 210 of the organic light-emitting diode OLED may be electrically connected to the thin-film transistor TFT through contact holes defined in the second planarization insulating layer 116 and the first planarization insulating layer 115, and a contact metal CM disposed on the first planarization insulating layer 115.

The pixel electrode 210 may include a conductive oxide such as indium tin oxide (“ITO”), indium zinc oxide (“IZO”), zinc oxide (ZnO), indium oxide (In₂O₃), indium gallium oxide (“IGO”), and/or aluminum zinc oxide (“AZO”). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), and/or any combinations thereof. In another embodiment, the pixel electrode 210 may further include a layer on/under the reflective layer, the layer including ITO, IZO, ZnO, or In₂O₃.

A pixel-defining layer 117 may be disposed on the pixel electrode 210, the pixel-defining layer 117 defining an opening 117OP exposing a central portion of the pixel electrode 210. The pixel-defining layer 117 may include an organic insulating material and/or an inorganic insulating material. The opening 117OP may define the emission area of light emitted from the organic light-emitting diode OLED. In an embodiment, the size/width of the opening 117OP may correspond to the size/width of the emission area. Accordingly, the size and/or width of the pixel PX may depend on the size and/or width of the opening 117OP of the pixel-defining layer 117.

The intermediate layer 220 may include an emission layer 222 formed to correspond to the pixel electrode 210. The emission layer 222 may include a polymer organic material (high-molecular weight organic material) or a low-molecular weight organic material emitting light having a preset color. In an alternative embodiment, the emission layer 222 may include an inorganic emission material or quantum dots.

In an embodiment, the intermediate layer 220 may include a first functional layer 221 and a second functional layer 223 respectively disposed under and on the emission layer 222. The first functional layer 221 may include, e.g., a hole transport layer (“HTL”), or include an HTL and a hole injection layer (“HIL”). The second functional layer 223 is an element disposed on the emission layer 222 and may include an electron transport layer (“ETL”) and/or an electron injection layer (“EIL”). Like the common electrode 230 described below, the first functional layer 221 and/or the second functional layer 223 may be common layers covering the substrate 100 entirely.

The common electrode 230 may be disposed on the pixel electrode 210 and may overlap the pixel electrode 210. The common electrode 230 may include a conductive material having a relatively low work function. In an embodiment, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), and/or any alloys thereof. In an alternative embodiment, the common electrode 230 may further include a layer on the (semi) transparent layer, the layer including ITO, IZO, ZnO, and/or In₂O₃. The common electrode 230 may be formed as one body to cover the substrate 100 entirely.

The encapsulation layer 300 may be disposed on the display element layer DEL and may cover the display element layer DEL. The encapsulation layer 300 may include at least one inorganic encapsulation layer and at least one organic encapsulation layer. In an embodiment. In an embodiment, it is shown in FIG. 12 that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic-based resin, an epoxy-based resin, polyimide, and polyethylene. In an embodiment, the organic encapsulation layer 320 may include acrylate. The organic encapsulation layer 320 may be formed by hardening a monomer or coating a polymer. The organic encapsulation layer 320 may be transparent.

Though not shown, a touch sensor layer may be disposed on the encapsulation layer 300. An optical functional layer may be disposed on the touch sensor layer. The touch sensor layer may obtain coordinate information corresponding to an external input, e.g., a touch event. The optical functional layer may reduce the reflectivity of light (external light) incident toward the display apparatus 1 from outside, and/or improve the color purity of light emitted from the display apparatus 1. In an embodiment, the optical functional layer may include a retarder and/or a polarizer. The phase retarder may include a film-type retarder or a liquid crystal-type retarder. The phase retarder may include a λ/2 phase retarder and/or a λ/4 phase retarder. The polarizer may include a film-type polarizer or a liquid crystal-type polarizer. The film-type polarizer may include a stretched synthetic resin film, and the liquid crystal-type polarizer may include liquid crystals arranged in a predetermined arrangement. Each of the phase retarder and the polarizer may further include a protective film.

An adhesive member may be disposed between the touch sensor layer and the optical functional layer. For the adhesive member, a general adhesive member known in the art may be employed without limitation. The adhesive member may be a pressure sensitive adhesive (“PSA”) member.

In the mask assembly, the apparatus for manufacturing a display apparatus, and the method of manufacturing a display apparatus in an embodiment, because an interval between openings defined in the mask is maintained to be substantially the same or similar to each other, fine patterns may be deposited.

In addition, in the mask assembly, the apparatus for manufacturing a display apparatus, and the method of manufacturing a display apparatus in an embodiment, the display apparatus configured to display clear images may be manufactured.

In the mask assembly, the apparatus for manufacturing a display apparatus, and the method of manufacturing a display apparatus in an embodiment, because masks separated from each other are included, the mask may be freely replaced.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A mask assembly comprising:
a mask frame including an opening area; and
a mask sheet which shields at least a portion of the opening area and is disposed on the mask frame, the mask sheet comprising:
a clamping portion fixed to the mask frame;
a connection stick spaced apart from the clamping portion; and
a plurality of sub-masks arranged between the clamping portion and the connection stick and defining a pattern hole,
wherein the connection stick is disposed between sub-masks adjacent to each other among the plurality of sub-masks and supports each of the sub-masks, and end portions of the sub-masks disposed on the connection stick are spaced apart from each other.

2. The mask assembly of claim 1, wherein each of the sub-masks disposed on the connection stick is coupled to the connection stick through a plurality of welding points arranged in a row.

3. The mask assembly of claim 2, wherein the plurality of welding points is disposed in a direction perpendicular to a lengthwise direction of a sub-mask of the plurality of sub-masks.

4. The mask assembly of claim 1, wherein a width of the connection stick is in a range of about 5 millimeters to about 100 millimeters.

5. The mask assembly of claim 1, wherein a thickness of the connection stick is at least a thickness of a sub-mask of the plurality of sub-masks and is within a range of 1 millimeter or less.

6. The mask assembly of claim 1, wherein the sub-masks are tensioned in a first direction and fixed to the clamping portion and the connection stick.

7. The mask assembly of claim 6, wherein the mask sheet is tensioned in a second direction different from the first direction and is fixed to the mask frame.

8. The mask assembly of claim 1, further comprising a support stick disposed on the mask frame and crossing the opening area.

9. The mask assembly of claim 8, wherein the support stick defines an opening into which the connection stick is inserted.

10. An apparatus for manufacturing a display apparatus, the apparatus comprising:
a deposition source; and
a mask assembly facing the deposition source, the mask assembly comprising:
a mask frame including an opening area; and
a mask sheet which shields at least a portion of the opening area and is disposed on the mask frame, the mask sheet comprising:
a clamping portion fixed to the mask frame;
a connection stick spaced apart from the clamping portion; and
a plurality of sub-masks arranged between the clamping portion and the connection stick and defining a pattern hole,
wherein the connection stick is disposed between sub-masks adjacent to each other among the plurality of sub-masks and supports each of the sub-masks, and end portions of the sub-masks disposed on the connection stick are spaced apart from each other.

11. The apparatus of claim 10, wherein each of the sub-masks disposed on the connection stick is coupled to the connection stick through a plurality of welding points arranged in a row.

12. The apparatus of claim 11, wherein the plurality of welding points is disposed in a direction perpendicular to a lengthwise direction of a sub-mask of the plurality of sub-masks.

13. The apparatus of claim 10, wherein a width of the connection stick is in a range of about 5 millimeters to about 100 millimeters.

14. The apparatus of claim 10, wherein a thickness of the connection stick is at least a thickness of a sub-mask of the plurality of sub-masks and is within a range of 1 millimeter or less.

15. The apparatus of claim 10, wherein the sub-masks are tensioned in a first direction and fixed to the clamping portion and the connection stick.

16. The apparatus of claim 15, wherein the mask sheet is tensioned in a second direction different from the first direction and is fixed to the mask frame.

17. The apparatus of claim 10, further comprising a support stick disposed on the mask frame and crossing the opening area.

18. The apparatus of claim 17, wherein the support stick defines an opening into which the connection stick is inserted.

19. A method of manufacturing a display apparatus, the method comprising:
disposing a mask assembly and a substrate inside a chamber; and
passing, through the mask assembly, a deposition material supplied from a deposition source, and depositing the deposition material on the substrate,
wherein the mask assembly comprises:
a mask frame including an opening area; and
a mask sheet which shields at least a portion of the opening area and is disposed on the mask frame,
wherein the mask sheet comprises:
a clamping portion fixed to the mask frame;
a connection stick spaced apart from the clamping portion; and
a plurality of sub-masks arranged between the clamping portion and the connection stick and defining a pattern hole, and
the connection stick is disposed between sub-masks adjacent to each other among the plurality of sub-masks and supports each of the sub-masks, and end portions of the sub-masks disposed on the connection stick are spaced apart from each other.

20. The method of claim 19, wherein each of the sub-masks disposed on the connection stick is coupled to the connection stick through a plurality of welding points arranged in a row.

21. The method of claim 20, wherein the plurality of welding points is disposed in a direction perpendicular to a lengthwise direction of a sub-mask of the plurality of sub-masks.

22. The method of claim 19, wherein a width of the connection stick is in a range of about 5 millimeters to about 100 millimeters.

23. The method of claim 19, wherein a thickness of the connection stick is at least a thickness of a sub-mask of the plurality of sub-masks and is within a range of 1 millimeter or less.

24. The method of claim 19, wherein the sub-masks are tensioned in a first direction and fixed to the clamping portion and the connection stick.

25. The method of claim 24, wherein the mask sheet is tensioned in a second direction different from the first direction and is fixed to the mask frame.

26. The method of claim 19, wherein a support stick is disposed on the mask frame and crosses the opening area.

27. The method of claim 26, wherein the support stick defines an opening into which the connection stick is inserted.
